(19) United States
(12) Patent Application Publication
(10) Pub. No.: US 2010/0326712 A1
(43) Pub. Date: Dec. 30, 2010

(54) CIRCUIT BOARD AND METHOD FOR MANUFACTURING THE SAME

(75) Inventors: Masayoshi Kondo, Akita (JP); Toshio Komiyatani, Akita (JP)

Correspondence Address: Ditthavong Mori & Steiner, P.C., 918 Prince Street, Alexandria, VA, 22314, US

(73) Assignee: SUMITOMO BAKELITE CO., LTD., Tokyo (JP)

(21) Appl. No.: 12/865,731

(22) PCT Filed: Feb. 20, 2009
(86) PCT No.: PCT/JP2009/000738

§ 371 Date: Aug. 2, 2010

(30) Foreign Application Priority Data
Feb. 29, 2008 (JP) 2008-048986
Feb. 29, 2008 (JP) 2008-048989
Apr. 14, 2008 (JP) 2008-104200
Apr. 14, 2008 (JP) 2008-104208
Jul. 3, 2008 (JP) 2008-174429
Jul. 3, 2008 (JP) 2008-174430

(51) Int. Cl. H05K 1/09; H05K 3/36

(52) U.S. Cl. 174/257; 29/830

(57) ABSTRACT

There are provided a circuit board, which has little outflow of an interlayer adhesive to be used for a multilayer lamination while keeping a connection reliability, and a method for manufacturing the circuit board. The circuit board (68) is characterized in that a first substrate (16) having a first base (12) and a conductor post (45) composed of a protrusion (14) projecting from the first base (12) and a metallic cover layer (15) covering the protrusion (14), and a second substrate (18) having a second base (19) and a conductor circuit (17) are laminated and adhered through an interlayer adhesive (13) and are alloyed at a bonding face (43) between the metallic cover layer (15) and the conductor circuit (17), and in that the cross-section, as viewed in the cross-section of the bonding face (43), of the metallic cover layer (15) has a shape which becomes wider from the bonding face (43) of the conductor circuit (17) toward the first substrate (16).

### TECHNICAL FIELD

The present invention relates to a circuit board and a method for manufacturing the same.

### BACKGROUND ART

Recent electronic devices assembled with a higher density have accelerated multilayering of a circuit board such as a flexible printed circuit board used in such a device. A build-up method is technique employed for forming such a multilayer circuit board by lamination. A build-up method refers to a method in which interlayer connection is formed between monolayers while a resin layer made of a resin alone and a conductor layer are piled.

Such build-up methods are generally classified into those where a via hole is formed in a resin layer before forming interlayer connection and those where an interlayer connecting part is formed before laminating resin layers. Furthermore, different types of interlayer connecting parts are used, depending on, for example, whether a via hole is formed by a plating or conductive paste.

There has been disclosed technique allowing for stacked via, densification and more compact interconnection designing, wherein a fine via hole for interlayer connection is formed in a resin layer by laser and the via hole is filled with a conductive adhesive such as a copper paste for electric connection (see, for example, Patent Document 1.

However, this method may be inadequately reliable because interlayer electric connection is achieved through a conductive adhesive. Furthermore, the method requires advanced techniques for filling a fine via hole with a conductive adhesive, and cannot, therefore, deal with further requirement for a finer interconnection pattern.

Thus, in place of the approach that a via hole is filled with a conductive adhesive, a metal protrusion (conductor post) is employed. However, even in the case where a conductor post is used, there has been disclosed a procedure where the conductor post physically removes an interlayer adhesive during interlayer connection to form connection with a conductor pad (see, for example, Patent Document 2).

However, since in this method, an interlayer adhesive between a conductor post and a conductor pad is removed at a high temperature during, for example, pressing while the conductor post is molten to achieve electric connection, variation in an internal temperature of the press may cause the interlayer adhesive to first cure, leading to inadequate connection reliability. Furthermore, because the system becomes hot, the interlayer adhesive may flow out to the outside of the circuit board, leading to reduced precision in a plate thickness or contamination of neighboring circuit boards by the outflowing adhesive.

Patent Document 1: Japanese Patent Application Laid-open No. 1996-316598.

Patent Document 2: Japanese Patent Application Laid-open No. 2000-183528.

### DISCLOSURE OF THE INVENTION

In view of the above situation, an objective of the present invention is to provide a circuit board with higher connection reliability and a manufacturing process for such a circuit board.

According to the present invention, a circuit board is characterized in that a first substrate having a first base and a conductor post composed of a protrusion projecting from said first base and a metallic cover layer covering said protrusion, and a second substrate having a second base and a conductor circuit are laminated and adhered through an interlayer adhesive and are alloyed at a bonding face between said metallic cover layer and said conductor circuit, and in that the cross-section, as viewed in the cross-section of said bonding face, of said metallic cover layer has a shape which becomes wider from said bonding face of said conductor circuit toward said first substrate.

In this circuit board, the cross-section of the metallic cover layer as viewed in the cross-section of the bonding face has a shape which becomes wider from the bonding face of the conductor circuit toward the first substrate. Thus, the metallic cover layer has a substantially uniform thickness between the first base and the second base, providing a circuit board with improved connection reliability.

According to the present invention, there is provided a method of manufacturing a circuit board comprising; preparing a first substrate having a first base and a conductor post composed of a protrusion projecting from said first base and a metallic cover layer covering said protrusion; preparing a second substrate having a second base and a conductor circuit formed in one side of said second base and receiving said conductor post; applying an interlayer adhesive to the side of said conductor post or the side of said conductor circuit, said conductor post and said conductor circuit being disposed so as to face each other, to be heat-pressed (a first step); curing said interlayer adhesive by heating after the first step (a second step); and after the second step, melting said metallic cover layer to initiate metal bonding of said conductor post with said conductor circuit (a bonding step).

Thus, the interlayer adhesive is cured before the metallic cover layer is molten, and therefore, there can be provided a process for manufacturing a circuit, where outflow of the interlayer adhesive can be reduced and productivity and an yield can be improved.

The interlayer adhesive may contain a polyfunctional epoxy resin (a) having three or more glycidyl ether groups with an epoxy equivalent of 100 to 300, a carboxyl-containing compound (b) having a melting point of 50° C. or more and 230° C. or less, and a curing agent (c). The carboxyl-containing compound (b) may have a boiling point or decomposition point of 240° C. Furthermore, it may contain a synthetic rubber elastomer. It can contain, as a curing agent (c), a novolac phenol resin.

The present invention can provide a circuit board with improved connection reliability.

### BRIEF DESCRIPTION OF THE DRAWINGS

The above objectives and other objectives, features and advantages of the present invention will be further understood with reference to preferred embodiments described below and the accompanying drawings below.

FIG. 1 is a cross-sectional view showing a first and a second substrates of this embodiment.

FIG. 2 is a cross-sectional view showing the first step of this embodiment.

FIG. 3 is a cross-sectional view showing the second step of this embodiment.

FIG. 4 is a cross-sectional view showing the bonding step of this embodiment.

FIG. 5 is a cross-sectional photographic image showing a part of a circuit board of this embodiment.

FIG. 6 is a cross-sectional photographic image of a bonding part showing a conventional example.

### BEST MODE FOR CARRYING OUT THE INVENTION

Embodiments of the present invention will be described with reference to the drawings. In all the drawings, common elements are denoted by identical symbols, which will not be detailed as appropriate.

FIGS. 1 to 4 are cross-sectional views showing one embodiment of a process for manufacturing a circuit board according to the present invention.

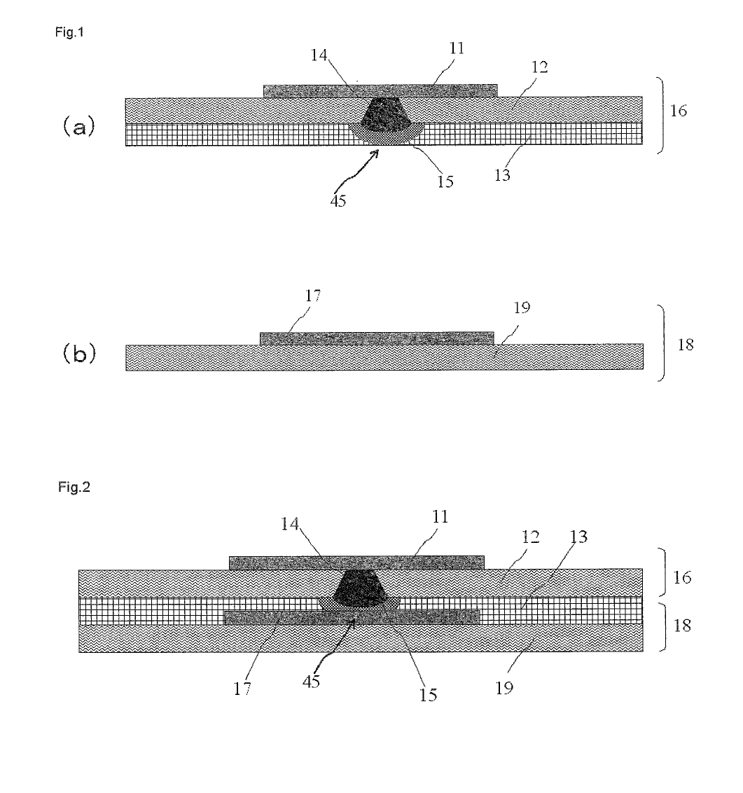

FIGS. 1(a) and 1(b) are cross-sectional views of the first and the second substrates, respectively. FIGS. 2, 3 and 4 are cross-sectional views of the first step, the second step and the bonding step, respectively.

As shown in FIG. 4, in a circuit board 68 in this embodiment, a first substrate 16 having a first base 12 and a conductor post 45 composed of a protrusion 14 projecting from the first base 12 and a metallic cover layer 15 covering the protrusion 14, and a second substrate 18 having a second base 19 and a conductor circuit 17 are laminated and adhered through an interlayer adhesive 13 and are alloyed at a bonding face 43 between the metallic cover layer 15 and the conductor circuit 17, to form a metal alloy layer 41.

Furthermore, the cross-section, as viewed in the cross-section of the bonding face 43, of the metallic cover layer 15 has a shape which becomes wider from the bonding face 43 of the conductor circuit 17 toward the first substrate 16.

The first and the second bases 12, 19 can be a fiber base or resin film. Examples of the fiber base include glass fiber bases such as glass woven fabric and glass unwoven fabric; inorganic fiber bases such as woven or unwoven fabric made of an inorganic compound other than glass; and organic fiber bases composed of an organic fiber such as an aromatic polyamide resin, a polyamide resin, an aromatic polyester resin, a polyester resin, a polyimide resin and a fluororesin. Examples of a resin film base include polyimide resin films such as a polyimide resin film, a polyether imide resin film and a polyamide-imide resin film; polyamide resin films such as a polyamide resin film; and polyester resin films such as a polyester resin film. Among these, polyimide resin films are generally preferable. Thus, an elastic modulus and heat resistance can be particularly improved.

A thickness of the bases 12, 19 is, but not limited to, preferably 5 to 100 μm, more preferably 8 to 50 μm, further preferably 12.5 to 25 μm. With a thickness being within the above range, flexibility can be particularly improved.

Examples of a metal foil composing of the conductor pad 11 and the conductor circuit 17 can be made of iron, aluminum, stainless steel or copper. Among these, copper is preferable as a metal foil material in the light of electric properties. A thickness of the metal foil is, but not limited to, preferably 5 to 35 μm, particularly preferably 8 to 18 μm.

The metallic cover layer 15 preferably has a drinking-cup shape expanding toward the first substrate 16. Thus, when it forms a bonding face 43 with the conductor circuit 17, it comes into contact with the conductor circuit 17 from its head, and therefore, the bonding face 43 is formed while the head is deformed, and finally, the cross-section of the metallic cover layer 15 as viewed in the cross-section of the bonding face 43 has a shape which becomes wider from the bonding face 43 of the conductor circuit 17 toward the first substrate 16. Furthermore, as viewed in the upper face of the bonding face 43, in the first base 12 and the surface facing the first base 12, a metallic cover layer 15 surrounding the protrusion 14 can be formed. This surrounding layer can have a shape such as, in addition to a circle, a square and an ellipse. The shape of the metallic cover layer 15 which becomes wider can be a shape with a diameter gradually increasing such as a drinking-cup shape which becomes wider toward the first substrate 16 and a bowl.

Examples of a metal constituting the metallic cover layer 15 include, but not limited to, at least one metal selected from the group consisting of gold, silver, nickel, tin, lead, zinc, bismuth, antimony and copper and an alloy containing the metal. For example, such an alloy can be selected from tin-lead, tin-silver, tin-zinc, tin-bismuth, tin-antimony, tin-silver-bismuth and tin-copper alloys, but, without being limited to a particular metal combination or composition, an optimal combination can be selected. The maximum of a thickness of the metallic cover layer 15 is, but not limited to, preferably 2 μm or more, particularly preferably 3 to 20 μm. With the thickness being within the above range, connection between the conductor post 45 and the conductor circuit 17 can be so stable that reliability can be improved.

A thickness of the interlayer adhesive 13 is, but not limited to, preferably 8 to 30 μm, particularly preferably 10 to 25 μm. With the thickness being within the above range, both adhesiveness and prevention of adhesive outflow can be improved. The interlayer adhesive 13 can be applied to the first base 12 as a fluid or by pressing with heating using, for example, a vacuum laminator, and the latter is more convenient and makes a thickness of the interlayer adhesive 13 stable.

The interlayer adhesive 13 preferably has a flux function which is a function of cleaning a metal surface; for example, an adhesive which can remove an oxide film in a metal surface or can reduce such an oxide film.

In a first preferable configuration, the interlayer adhesive 13 contains a polyfunctional epoxy resin (a) having three or more glycidyl ether groups with an epoxy equivalent of 100 to 300, a carboxyl-containing compound (b) having a melting point of 50° C. or more and 230° C. or less, and a curing agent (c).

The interlayer adhesive 13 contains a polyfunctional epoxy resin (a) having three or more glycidyl ether groups with an epoxy equivalent of 100 to 300. Thus, the interlayer adhesive 13 can be reliably heat resistant. Examples of the polyfunctional epoxy resin (a) include, but not limited to, phenol novolac epoxy resins, cresol novolac epoxy resins, glycidyl amine type epoxy resins, aminotriazine phenol novolac epoxy resins, aminotriazine cresol novolac epoxy resins, naphthalene framework type epoxy resins and cyclopentadiene type epoxy resins, which can be used alone or in combination. Among these, preferred are naphthalene framework type tetrafunctional epoxy resins, glycidyl amine type trifunctional epoxy resins and trifunctional solid epoxy resins. A content of the polyfunctional epoxy resin (a) is, but not limited to, preferably 60 parts by weight or more and 80 parts by weight or less to 100 parts by weight as the total of the polyfunctional epoxy resin (a) and the curing agent (c). With the content being within the above range, adhesiveness can be improved.

The interlayer adhesive 13 contains a carboxyl-containing compound (b) having a melting point of 50° C. or more and 230° C. or less. A boiling point or decomposition point of the carboxyl-containing compound (b) can be 240° C. or more. When a conductor post having a metallic cover layer and a conductor circuit are bonded through a metal by melting a metallic cover layer as described later, the carboxyl-containing compound removes an oxide film in the receiving conductor circuit and an oxide in the metallic cover layer surface to improve wettability. Generally, since a temperature in the metal bonding is often 240° C. or more, a boiling point or decomposition point of the carboxyl-containing compound (b) is preferably 240° C. or more. If the boiling point or the decomposition point is 240° C. or less, a void (cavity) may be formed between layers or delamination may occur, leading to decreased reliability. Furthermore, since the carboxyl-containing compound (b) is most activated when a temperature exceeds its melting point, the melting point is preferably 230° C. or less. If the melting point is 50° C. or less, the carboxyl-containing compound (b) may outflow from the interlayer adhesive layer, the melting point is preferably 50° C. or more.

A content of the carboxyl-containing compound (b) is preferably 3 parts by weight or more and 15 parts by weight or less to 100 parts by weight as the total of the polyfunctional epoxy resin (a) and the curing agent (c). With the content being within this range, the metal surface can be adequately reduced by the compound, resulting in satisfactory metal bonding. Furthermore, when it is used as a sheet carrier material, it can be favorably handled as a film.

Examples of the carboxyl-containing compound (b) include, but not limited to, 2,3-pyrazinedicarboxylic acid, cyclohexanedicarboxylic acid, cyclobutanedicarboxylic acid, benzoic acid, m-methylbenzoic acid, p-methylbenzoic acid, coumarin-3-carboxylic acid, benzophenone-2-carboxylic acid, sebacic acid, 1,2,3,4-cyclopentanetetracarboxylic acid, 2-biphenylcarboxylic acid and 4-biphenylcarboxylic acid, which can be used alone or in combination of two or more.

The interlayer adhesive 13 can further contain a synthetic rubber elastomer. Thus, when it is used as a sheet carrier material, the interlayer adhesive 13 exhibiting excellent film processability can be obtained. The synthetic rubber elastomer is preferably carboxylic acid-modified because its adhesiveness to a polyimide film is improved. For example, it can be a common rubber such as a carboxylic-acid-modified NBR, a carboxylic-acid-modified acrylic rubber and a carboxylic-acid-modified butadiene rubber which are commercially available.

A content of the synthetic rubber elastomer is, but not limited to, preferably 5 parts by weight or more and 30 parts by weight or less to 100 parts by weight as the total of the polyfunctional epoxy resin (a) and the curing agent (c). With the content being within this range, the interlayer adhesive 13 in which adhesiveness and heat resistance are well-balanced can be provided. Furthermore, a weight average molecular weight of the synthetic rubber elastomer is preferably 500,000 or more. Thus, an interlayer adhesive 13 exhibiting excellent moldability in pressing with heating can be provided.

The interlayer adhesive 13 can contain a novolac phenol resin as a curing agent (c). Preferable examples of novolac phenol resin include, but not limited to, aminotriazine novolac type phenol resins and aminotriazine cresol novolac type phenol resins. The presence of an amino group causes a reaction of some epoxy groups due to heat during application, leading to B stage. Thus, outflow during laminating press can be prevented. Furthermore, nitrogen in the triazine moiety contributes to flame retardancy. A content of the novolac phenol resin is, but not limited to, preferably 0.8 to 1.2 equivalent to the polyfunctional epoxy resin (a) in the present invention. With the content being within this range, an interlayer adhesive 13 which is excellent in curability and warpage can be provided.

The interlayer adhesive 13 can further contain a coupling agent for improving adhesiveness, a defoamer or leveling agent for minimizing foaming or repelling during application, a small amount of a curing accelerator for adjusting a gelling time and/or an inorganic filler.

A second preferable interlayer adhesive contains a resin (A) having a phenolic hydroxy group such as a phenol novolac resin, a cresol novolac resin, an alkylphenol novolac resin, a resol resin and a polyvinylphenol resin, and a curing agent (B) for the resin. Examples of the curing agent include epoxy resins prepared by epoxidation of a phenolic base such as a bisphenol, a phenol novolac, an alkylphenol novolac, a biphenol, a naphthol and a resorcinol compound or a base having an aliphatic, alicyclic or unsaturated aliphatic skeleton, or isocyanate compounds.

A content of the resin having a phenolic hydroxy group is preferably 20 parts by weight or more and 80 parts by weight or less to the total amount of the adhesive, and if it is less than 20 parts by weight, a function of cleaning a metal surface is deteriorated while if it is more than 80 parts by weight, an inadequately cured product is obtained, so that bonding strength and reliability may be disadvantageously deteriorated. The resin or the compound acting as a curing agent is preferably 20 parts by weight or more and 80 parts by weight or less to the total amount of the adhesive. The interlayer adhesive can contain, if necessary, a coloring agent, an inorganic filler, various coupling agents and/or a solvent.

A third preferable interlayer adhesive contains an epoxy resin (C) prepared by epoxidation of a phenolic base such as a bisphenol, a phenol novolac, an alkylphenol novolac, a biphenol, a naphthol and a resorcinol compound or a base having an aliphatic, alicyclic or unsaturated aliphatic skeleton; a curing agent (D) for the above epoxy resin which has an imidazole ring; and a curable antioxidant (E). Examples of the curing agent having an imidazole ring include imidazole, 2-methylimidazole, 2-ethyl-4-methylimidazole, 2-phenylimidazole, 1-benzyl-2-methylimidazole, 2-undecylimidazole, 2-phenyl-4-methylimidazole and bis(2-ethyl-4-methyl-imidazole). The curable antioxidant is a compound which acts as an antioxidant and can react with a curing agent to be cured; examples include compounds having a benzylidene structure, 3-hydroxy-2-naphthoic acid, pamoic acid, 2,4-dihydroxybenzoic acid and 2,5-dihydroxybenzoic acid.

A content of the epoxy resin is preferably 30 parts by weight or more and 99 parts by weight or less to the total amount of the adhesive, and if it is less than 30 parts by weight, an inadequately cured product may be disadvantageously produced.

In addition to the above two components, the adhesive can contain a thermosetting resin such as a cyanate resin, an acrylic acid resin, a methacrylic acid resin and a maleimide resin and/or a thermoplastic resin. Furthermore, it can contain, if necessary, a coloring agent, an inorganic filler, various coupling agents and/or a solvent.

A content of the compound having an imidazole ring which acts as a curing agent for the above epoxy resin and the above curable antioxidant in combination is preferably 1 parts by weight or more and 20 parts by weight or less to the total amount of the adhesive, and if it is less than 1 part by weight, a function of cleaning a metal surface is deteriorated and the epoxy resin may be inadequately cured, which is undesirable. If it is more than 10 parts by weight, the curing reaction proceeds so rapidly that the adhesive layer can be less fluid, which is undesirable. The curing agent for the above epoxy compound and the curable antioxidant can be used in combination or alone.

The interlayer adhesive can be prepared by, for example, dissolving a solid resin (A) having a phenolic hydroxy group and a solid resin (B) acting as a curing agent in a solvent; dissolving a solid resin (A) having a phenolic hydroxy group in a liquid resin (B) acting as a curing agent; dissolving a solid resin (B) acting as a curing agent in a liquid resin (B) having a phenolic hydroxy group; or dissolving or dispersing a compound (D) having an imidazole ring which acts as a curing agent for the epoxy resin and a curable antioxidant (E) in a solution of a solid epoxy resin (C) dissolved in a solvent. Examples of a solvent used include acetone, methyl ethyl ketone, methyl isobutyl ketone, cyclohexane, toluene, butyl cellosolve, ethyl cellosolve, N-methylpyrrolidone and γ-butyrolactone. The solvent preferably has a boiling point of 200° C. or less.

There will be described one embodiment of a method for manufacturing a circuit board of the present invention with reference to FIGS. 1 to 4.

### Step A

First, as shown in FIG. 1(a), a first substrate 16 having a first base 12 and a conductor post 45 composed of a protrusion 14 projecting from the first base 12 and a metallic cover layer 15 covering the protrusion 14 is prepared. In one side of the first base 12, a conductor pad 11 is formed. Next, as shown in FIG. 1(b), a second substrate 18 having a second base 19 and a conductor circuit 17 formed in one side of the second base 19 and receiving the conductor post 45 is prepared.

### Step B

Subsequently, a first step is carried out as shown in FIG. 2, where an interlayer adhesive 13 is applied to the side of the conductor post 45 or the side of the conductor circuit 17, and the conductor post 45 and the conductor circuit 17 are disposed so as to face each other to be heat-pressed.

### Step C

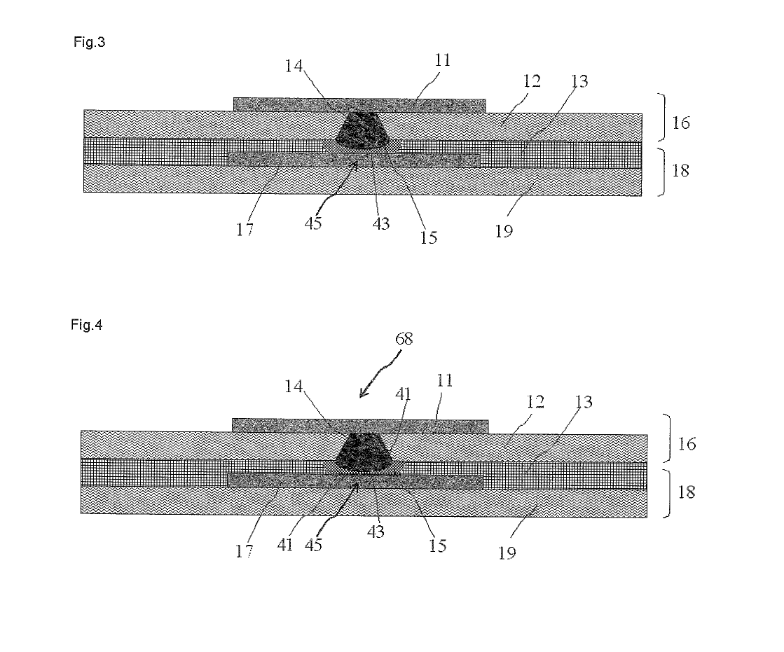

Next, a second step is carried out as shown in FIG. 3, where the interlayer adhesive 13 is cured by heating after the first step.

### Step D

Then, a bonding step is carried out, where after the second step, the metallic cover layer 15 is molten to initiate metal bonding of the conductor post 45 with the conductor circuit 17.

By a manufacturing process containing these steps, a circuit board 68 can be provided.

There will be described the individual steps.

### Step A

A first substrate 18 having a conductor post 45 and a second substrate 18 having a conductor circuit 17 receiving the conductor post 45 are prepared (FIGS. 1(a) and (b)).

For a protrusion 14, for example, a copper post is formed using a paste or by plating. Subsequently, a metallic cover layer 15 is formed from, for example, an alloy, to give the conductor post 45. In terms of a height of the protrusion 14, it protrudes by, but not limited to, preferably 2 to 30 μm, particularly preferably 5 to 15 μm from the side opposite to the side having a conductor pad 11 in a first base 12. With the height being within the above range, connection between the conductor post 45 and the conductor circuit 17 is stable.

### Step B

There will be described the first step (FIG. 2). In the first step, an interlayer adhesive 13 is applied to the side of the conductor post 45 or the side of the conductor circuit 17; the conductor post 45 and the conductor circuit 17 are disposed so as to face each other to be heat-pressed; the interlayer adhesive 13 covering the metallic cover layer 15 is removed while the head of the metallic cover layer 15 is deformed.

In advance, the first substrate 16 and the second substrate 18 are aligned by a method where a mark formed as a conductor pattern is read by an image-identifying machine, or where a pin is used for alignment. The aligned substrate is pressed in vacuo at a predetermined temperature and a predetermined pressure.

The predetermined temperature is preferably 150 to 200° C., particularly preferably 170 to 190° C. With the temperature being within the above range, the interlayer adhesive 13 softens while the metallic cover layer 15 is not yet molten, so that the interlayer adhesive 13 between the metallic cover layer 15 and the conductor circuit 17 can be removed. If the temperature is lower than the range, the interlayer adhesive 13 inadequately softens while if the temperature is higher than the range, the metallic cover layer 15 is molten, so that the interlayer adhesive 13 cannot be completely removed.

The predetermined pressure is preferably 1 to 3 MPa, particularly preferably 1.5 to 2.5 MPa. With the pressure being within the above range, the metallic cover layer 15 is so deformed that the interlayer adhesive 13 between the metallic cover layer 15 and the conductor circuit 17 can be removed. The deformed metallic cover layer 15 has a shape that, as viewed in the cross-section, it becomes wider from the interface between the metallic cover layer 15 and the conductor circuit 17, and the deformation is maintained.

A processing time is preferably 20 sec or more and 10 min or less, particularly preferably 3 to 7 min. With the processing time being within the above range, the interlayer adhesive 13 can be removed and the head of the metallic cover layer 15 can be crushed.

### Step C

Next, there will be described the second step (FIG. 3). In the second step, the interlayer adhesive 13 is thermally cured. A temperature is preferably 150 to 200° C., particularly preferably 170 to 190° C. A processing time is preferably 30 min or more and 120 min or less, particularly preferably 45 to 75 min. With the processing conditions being within the above ranges, the interlayer adhesive 13 is cued and thus adhesion between the first substrate 16 and the second substrate 18 becomes stronger. Here, the deformed shape of the head of the metallic cover layer 15 is unchanged.

### Step D

There will be described the bonding step (FIG. 4). The metallic cover layer 15 is molten and bonded to the conductor circuit 17, and furthermore, a metal alloy layer 41 is formed between the metallic cover layer 15 and the conductor post 45, and between the metallic cover layer 15 and the conductor circuit 17. After the metallic cover layer 15 is molten, the shape of the deformed head is still maintained.

A reflow temperature is preferably 240 to 280° C., particularly preferably 250 to 270° C. With the temperature being within the above range, a stable metal alloy layer 41 can be formed and reliability in electric connection between the first substrate 16 and the second substrate 18 can be improved.

A processing time is preferably 1 to 10 min, particularly preferably 3 to 8 min. With the time being within the range, a metal alloy layer 41 is formed, resulting in improvement in reliability and productivity.

FIG. 5 is a cross-sectional photographic image showing a part of the circuit board 68. A first substrate 16 has a first base 12 and a conductor post 45 composed of a protrusion 14 projecting from the first base 12 and a metallic cover layer 15 covering the protrusion 14. In one side of the first base 12, a conductor pad 11 is formed. A second substrate 18 has a second base 19 and a conductor circuit 17. The first substrate 16 and the second substrate 18 are laminated and adhered through the interlayer adhesive 13. The bonding face 43 between the metallic cover layer 15 and the conductor circuit 17 is alloyed to form a metal alloy layer 41.

The cross-section, as viewed in the cross-section of the bonding face 43, of the metallic cover layer 15 has a shape which becomes wider from the bonding face 43 of the conductor circuit 17 toward the first substrate 16.

Steps A to D may not be necessarily continuously carried out, but a continuous process is preferable because it leads to reduction in a work time and a stable substrate.

There are no particular restrictions to an apparatus as long as it can meet the requirements for a predetermined temperature, a pressure and a processing time from the first step to the bonding step, and a hot plate preheated to a predetermined temperature or a rapid heating heater can be used.

Although the embodiment of the present invention has been described with reference to the drawings, the embodiment is illustrative only and various configurations other than those described above can be employed.

For example, although there has been described the step of laminating and adhering the first substrate 16 and the second substrate 18 in this embodiment, an alternative process for manufacturing a circuit board can be employed, in which a conductor circuit 17 is formed on a first substrate 16 and a substrate having a conductor post 45 is laminated and adhered to the upper layer of the first substrate 16. Thus, when a plurality of layers are desired, the layers can be added to the first substrate 16 and the second substrate 18 to give a multilayer circuit board. Then, semiconductor elements can be mounted on the multilayer circuit board to provide a semiconductor device.

### EXAMPLES

The examples were carried out in accordance with the steps illustrated in Table 1.

In Table 1, AA denotes “Good”, and CC denotes “Defective”.

TABLE 1

| | | | | | Comparative | Comparative |
|---|---|---|---|---|---|---|
| | Example 1 | Example 2 | Example 3 | Example 4 | Example 1 | Example 2 |
| First step | 180° C. | 180° C. | 180° C. | 180° C. | 260° C. | None |
| | 2 MPa | 2 MPa | 2 MPa | 2 MPa | 2 MPa | |
| | 5 min | 5 min | 1 min | 5 min | 5 min | |
| Second step | 180° C. | 180° C. | 180° C. | 180° C. | 180° C. | 180° C. |
| | 60 min | 60 min | 60 min | 60 min | 60 min | 60 min |
| Bonding step | 260° C. | 260° C. | 260° C. | 260° C. | None | 260° C. |
| | 5 min | 5 min | 3 min | 5 min | | 5 min |
| Outflow of | AA | AA | AA | AA | CC | AA |
| an adhesive | | | | | | |
| Bonding rate | AA | AA | AA | AA | AA | CC |
| Connection | AA | AA | AA | AA | AA | CC |
| reliability | | | | | | |

### Example 1

First, a two-layer single-sided circuit substrate with a copper foil having a thickness of 12 μm and a polyimide film with a thickness of 25 μm as a base (Ube Industries, Ltd., SE1310) was prepared, and a via with a diameter of 50 μm was formed by UV laser from the side opposite to the copper foil. After plasma desmear, copper plating and lead-free solder plating were conducted to form a copper protrusion projecting from the base by 8 μm, and then the protrusion was metal-coated to a thickness of 15 μm by lead-free solder plating to form a conductor post. Subsequently, a circuit was formed by etching to provide a first substrate. Then, a two-layer double-sided circuit substrate with a copper foil with a thickness of 12 μm and a polyimide film with a thickness of 25 μm as a base (Mitsui Chemicals Inc., NFX-2ABEPFE(25T)) was etched to form a circuit, and thus to provide a second substrate.

To the conductor post side of this first substrate was thermally compressed an interlayer adhesive with a thickness of 13 μm by a vacuum laminator under the conditions of 120° C. and 0.2 MPa.

The interlayer adhesive was as follows. In a vessel were weighed 40 parts by weight of a bisphenol-A type epoxy resin (Dainippon Ink And Chemicals, Incorporated Epiclon 830S), 10 parts by weight of a dicyclopentadiene type epoxy resin (DIC, HP-7200; epoxy equivalent: 258), 25 parts by weight of a novolac type phenol resin (Sumitomo Bakelite Co., Ltd. PR-53647), 25 parts by weight of an acrylic rubber (Nagase ChemteX Corporation, SG-708-6; weight average molecular weight: 700,000) and 100 parts by weight of acetone, and the mixture was stirred for dissolution, and to 100 parts by weight of the resin composition was added 5 parts by weight of sebacic acid (Kanto Chemical Co., Inc. Reagent grade; melting point: 131° C., boiling point: 294.5° C./133 hPa), and the mixture was stirred for dissolution to give a varnish. To an antistatic-treated PET film with a thickness of 25 μm as a releasable base was applied the varnish to a thickness of 13 μm after drying by a comma knife type coater to prepare, after drying, an interlayer adhesive.

The conductor post in the first substrate and the conductor circuit in the second substrate were aligned by image processing and laminated, and the laminate was, as the first step, thermally compressed by a vacuum press at 180° C. and 2 MPa for 5 min, then treated, as the second step, in an oven at 180° C. for 60 min, and finally, as the bonding step, reflowed at 260° C. for 5 min. Consequently, as shown in FIG. 5, the metal layer thus prepared had a shape in which the head of the solder is deformed and which became wider toward the first substrate as viewed in the cross-section, and it exhibited excellent connection stability and, in a temperature cycle reliability evaluation test (−25° C. to 125° C., 9 min each, 1000 cyc), a rate of resistance change was as good as 10% or less.

### Example 2

A procedure was conducted as described in Example 1, substituting the following interlayer adhesive for that in Example 1. For preparing an interlayer adhesive, in a vessel were weighed 40 parts by weight of a naphthalene framework type tetrafunctional epoxy resin (Dainippon Ink And Chemicals, Incorporated., Development No. EXA-4700; epoxy equivalent: 162), 30 parts by weight of a dicyclopentadiene type epoxy resin (Dainippon Ink And Chemicals, Incorporated, HP-7200; epoxy equivalent: 258), 30 parts by weight of a novolac type phenol resin (Sumitomo Bakelite Co., Ltd. PR-53647) and 100 parts by weight of acetone, and the mixture was stirred for dissolution, and to 100 parts by weight of the resin composition was added 3 parts by weight of p-toluic acid having a melting point of 180° C. (Kanto Chemical Co., Inc., Reagent grade; boiling point: 275° C.) and the mixture was stirred for dissolution to give a varnish. To an antistatic-treated PET film with a thickness of 25 μm as a releasable base was applied the varnish to a thickness of 13 μm after drying by a comma knife type coater to prepare, after drying, an interlayer adhesive.

Consequently, as shown in FIG. 5, the metal layer thus prepared had a shape in which the head of the solder is deformed and which became wider toward the first substrate as viewed in the cross-section, and it exhibited excellent connection stability and, in a temperature cycle reliability evaluation test (−25° C. to 125° C., 9 min each, 1000 cyc), a rate of resistance change was as good as 10% or less.

### Example 3

A procedure was conducted as described in Example 1, except that the first step in Example 1 was conducted by a vacuum press at 180° C. and 2 MPa, the bonding step was conducted in a reflow system at 260° C. for 3 min, and an interlayer adhesive described below was used.

In a vessel were weighed 20 parts by weight of a glycidyl amine type trifunctional epoxy resin (JER Company, Epicoat 630; epoxy equivalent: 100), 40 parts by weight of a dicyclopentadiene type epoxy resin (Dainippon Ink And Chemicals, Incorporated, HP-7200; epoxy equivalent: 258), 40 parts by weight of a novolac type phenol resin (Sumitomo Bakelite Co., Ltd. PR-53647) and 100 parts by weight of acetone, and the mixture was stirred for dissolution, and to 100 parts by weight of the resin composition was added 15 parts by weight of 4-biphenylcarboxylic acid having a melting point of 225° C. (Kanto Chemical Co., Inc., Reagent grade; boiling point: 225° C. or more) and the mixture was stirred for dissolution to give a varnish. This was applied by a comma coater to such a thickness that an adhesive thickness was to be 13 μm and dried as described in Example 1, to provide an interlayer adhesive.

Consequently, as shown in FIG. 5, the metal layer thus prepared had a shape in which the head of the solder is deformed and which became wider toward the first substrate as viewed in the cross-section, and it exhibited excellent connection stability and, in a temperature cycle reliability evaluation test (−25° C. to 125° C., 9 min each, 1000 cyc), a rate of resistance change was as good as 10% or less.

### Example 4

A procedure was conducted as described in Example 1, substituting the following interlayer adhesive for that in Example 1.

A varnish was applied by a comma coater to such a thickness that an adhesive thickness was to be 13 μm and dried as described in Example 1, substituting benzophenone-2-carboxylic acid having a melting point of 128° C. (Kanto Chemical Co., Inc.) for p-toluic acid in Example 2, to provide an interlayer adhesive.

Consequently, as shown in FIG. 5, the metal layer thus prepared had a shape in which the head of the solder is deformed and which became wider toward the first substrate as viewed in the cross-section, and it exhibited excellent connection stability and, in a temperature cycle reliability evaluation test (−25° C. to 125° C., 9 min each, 1000 cyc), a rate of resistance change was as good as 10% or less.

### Comparative Example 1

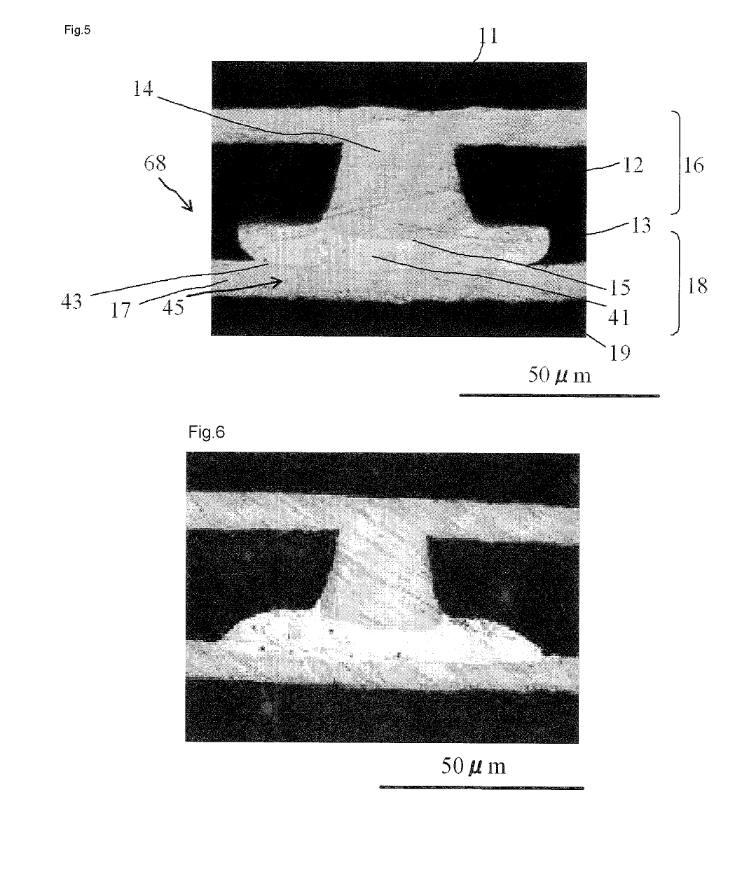

A procedure was conducted as described in Example 1, except that the first step in Example 1 was conducted using a vacuum press at 260° C. and 2 MPa for 5 min and a solder was fused without reflow. Consequently, as shown in FIG. 6, the metal layer obtained had a shape that, as viewed in the cross-section, spread toward the second substrate. Furthermore, since the solder was fused before curing of the interlayer adhesive 13, outflow from the interlayer adhesive was observed.

### Comparative Example 2

A procedure was conducted as described in Example 1, except that the first step was omitted. Consequently, the interlayer adhesive was not removed, as in the first step, from the head of the metallic cover layer, leading to inadequate connection with a conductor circuit.

This application claims the priority to Japanese Patent Application Nos. 2008-48986, 2008-48989, 2008-104200, 2008-104208, 2008-174430 and 2008-174429, the disclosures of which are incorporated by reference herein in their entirety.

1. A circuit board, wherein
a first substrate having a first base and a conductor post composed of a protrusion projecting from said first base and a metallic cover layer covering said protrusion, and
a second substrate having a second base and a conductor circuit
are laminated and adhered through an interlayer adhesive and are alloyed at a bonding face between said metallic cover layer and said conductor circuit, and wherein
the cross-section, as viewed in the cross-section of said bonding face, of said metallic cover layer has a shape which becomes wider from said bonding face of said conductor circuit toward said first substrate.

2. The circuit board as claimed in claim 1, wherein in said first base and the surface facing said first base, said metallic cover layer is formed so as to surround said protrusion.

3. The circuit board as claimed in claim 1, wherein said metallic cover layer has a drinking-cup shape which becomes wider toward said first substrate.

4. The circuit board as claimed in claim 1, wherein said metallic cover layer is made of at least one metal selected from the group consisting of gold, silver, nickel, tin, lead, zinc, bismuth, antimony and copper or an alloy containing said metal.

5. The circuit board as claimed in claim 1, wherein said interlayer adhesive contains a polyfunctional epoxy resin (a) having three or more glycidyl ether groups with an epoxy equivalent of 100 to 300, a carboxyl-containing compound (b) having a melting point of 50° C. or more and 230° C. or less, and a curing agent (c).

6. The circuit board as claimed in claim 5, wherein a boiling point or decomposition point of said carboxyl-containing compound (b) is 240° C. or more.

7. The circuit board as claimed in claim 5, further comprising a synthetic rubber elastomer.

8. The circuit board as claimed in claim 7, wherein said synthetic rubber elastomer has a weight average molecular weight of 500,000 or more.

9. The circuit board as claimed in claim 7, wherein said synthetic rubber elastomer is carboxylic-acid-modified.

10. The circuit board as claimed in claim 5, wherein said curing agent (c) contains a novolac phenol resin.

11. The circuit board as claimed in claim 10, wherein said novolac phenol resin is contained in a rate of 0.8 to 1.2 equivalents to said polyfunctional epoxy resin (a).

12. A method for manufacturing a circuit board, comprising:
preparing a first substrate having a first base and a conductor post composed of a protrusion projecting from said first base and a metallic cover layer covering said protrusion;
preparing a second substrate having a second base and a conductor circuit formed in one side of said second base and receiving said conductor post;
applying an interlayer adhesive to the side of said conductor post or the side of said conductor circuit, said conductor post and said conductor circuit being disposed so as to face each other, to be heat-pressed (a first step);
curing said interlayer adhesive by heating after the first step (a second step); and
after the second step, melting said metallic cover layer to initiate metal bonding of said conductor post with said conductor circuit (a bonding step).

13. The method for manufacturing a circuit board as claimed in claim 12, wherein in said first step, a temperature is 150° C. or more and 200° C. or less, and a pressure is 1 MPa or more and 3 MPa or less.

14. The method for manufacturing a circuit board as claimed in claim 12, wherein in said first step, said metallic cover layer is deformed.

15. The method for manufacturing a circuit board as claimed in claim 14, wherein said deformed metallic cover layer has a shape with a diameter gradually increasing from the bonding face of said conductor circuit as viewed in the cross-section of said circuit board.

16. The method for manufacturing a circuit board as claimed in claim 12, wherein said second step is conducted at a temperature of 150° C. or more and 200° C. or less in a substantially pressureless atmosphere.

17. The method for manufacturing a circuit board as claimed in claim 12, wherein said bonding step is conducted at a temperature of 240° C. or more and 280° C. or less.

18. The method for manufacturing a circuit board as claimed in claim 14, wherein said metallic cover layer is molten while said metallic cover layer maintains its deformed shape.

19. The method for manufacturing a circuit board as claimed in claim 12, wherein a processing time of said first step is 20 sec or more and 10 min or less.

20. The method for manufacturing a circuit board as claimed in claim 12, wherein a processing time of said second step is 30 min or more and 120 min or less.

21. The method for manufacturing a circuit board as claimed in claim 12, wherein a processing time of said bonding step is 1 min or more and 10 min or less.

22. The method for manufacturing a circuit board as claimed in claim 12, wherein said interlayer adhesive contains a polyfunctional epoxy resin (a) having three or more glycidyl ether groups with an epoxy equivalent of 100 to 300, a carboxyl-containing compound (b) having a melting point of 50° C. or more and 230° C. or less, and a curing agent (c).

23. The method for manufacturing a circuit board as claimed in claim 22, wherein a boiling point or decomposition point of said carboxyl-containing compound (b) is 240° C. or more.

24. The method for manufacturing a circuit board as claimed in claim 22, wherein said circuit board further includes a synthetic rubber elastomer.

25. The method for manufacturing a circuit board as claimed in claim 24, wherein said synthetic rubber elastomer has a weight average molecular weight of 500,000 or more.

26. The method for manufacturing a circuit board as claimed in claim 24, wherein said synthetic rubber elastomer is carboxylic-acid-modified.

27. The method for manufacturing a circuit board as claimed in claim 22, wherein said curing agent (c) contains a novolac phenol resin.

28. The method for manufacturing a circuit board as claimed in claim 27, wherein said novolac phenol resin is contained in a rate of 0.8 to 1.2 equivalents to said polyfunctional epoxy resin (a).
